(19) United States
(12) Patent Application Publication
(10) Pub. No.: US 2025/0206022 A1
(43) Pub. Date: Jun. 26, 2025

(54) NOZZLE PLATE, DROPLET EJECTION HEAD, DROPLET EJECTING APPARATUS, AND NOZZLE PLATE MANUFACTURING METHOD

(71) Applicant: Konica Minolta, Inc., Tokyo (JP)

(72) Inventors: Yoshiyuki Ogawa, Osaka-shi, Osaka (JP); Hiroshi Kajita, Osaka-shi, Osaka (JP)

(73) Assignee: Konica Minolta, Inc., Tokyo (JP)

(21) Appl. No.: 18/848,042

(22) PCT Filed: Mar. 17, 2022
(86) PCT No.: PCT/JP2022/012125

§ 371 Date: Sep. 17, 2024

(51) Int. Cl. B41J 2/14; B41J 2/16

(52) U.S. Cl. CPC B41J 2/1433; B41J 2/14233; B41J 2/162; B41J 2/1623; B41J 2/1628; B41J 2/1629; B41J 2/1631; B41J 2/1645; B41J 2002/14475

(57) ABSTRACT

A nozzle plate made of a single-crystal silicon substrate includes a plurality of nozzle channels that penetrates the nozzle plate, the plurality of nozzle channels each including a nozzle and each capable of ejecting droplets from the nozzle. The single-crystal silicon substrate includes a first surface and a second surface opposite the first surface, the nozzle is formed on the second surface, and the first surface and the second surface are {110} planes.

### TECHNICAL FIELD

The present invention relates to a nozzle plate, a droplet ejection head, a droplet ejecting apparatus, and a nozzle plate manufacturing method.

### BACKGROUND ART

As a method of manufacturing a nozzle plate of a droplet ejection head included in a droplet ejecting apparatus, there has been known a method of forming a nozzle channel by performing anisotropic wet etching on a single-crystal silicon substrate (e.g., refer to Patent Document 1)

### CITATION LIST

### Patent Literature

Patent Document 1: Japanese Patent No. 5519263

When anisotropic wet etching is performed on a single-crystal silicon substrate whose surface has the crystal orientation of a {100} plane, corrosion proceeds in a certain direction. Therefore, it is possible to form only a nozzle channel in which the opening of the surface facing the droplet ejection surface is square. As a result, in a case where a plurality of nozzle channels is arranged side by side in a single-crystal silicon substrate, the number of nozzle channels is smaller in a nozzle channel having a square opening than in a nozzle channel having an elongated opening.

### SUMMARY

The present invention has been made in view of such circumstances. An object of the present invention is to provide a nozzle plate, a droplet ejection head, a droplet ejecting apparatus, and a nozzle plate manufacturing method that can increase the density of nozzles.

According to the first aspect of the invention,
a nozzle plate made of a single-crystal silicon substrate, comprises:
a plurality of nozzle channels that penetrates the nozzle plate, the plurality of nozzle channels each including a nozzle and each capable of ejecting droplets from the nozzle,
wherein
the single-crystal silicon substrate includes a first surface and a second surface opposite the first surface,
the nozzle is formed on the second surface, and
the first surface and the second surface are {110} planes.

According to the second aspect of the invention,
in the nozzle plate, each of the plurality of nozzle channels includes a surface on a {111} plane.

According to the third aspect of the invention,
in the nozzle plate,
each of the plurality of nozzle channels includes a nozzle tapered portion having a channel area that gradually decreases from the first surface toward the second surface, the channel area being a cross-sectional area perpendicular to a droplet ejection direction, and
the nozzle tapered portion includes a {111} plane.

According to the fourth aspect of the invention,
in the nozzle plate, the nozzle tapered portion is composed of {111} planes.

According to the fifth aspect of the invention,
in the nozzle plate,
each of the plurality of nozzle channels includes a nozzle straight portion on a side of the nozzle tapered portion facing the second surface, and
a channel area of the nozzle straight portion is less than or equal to the channel area of the nozzle tapered portion.

According to the sixth aspect of the invention,
the nozzle plate further comprises:
a non-wet etching layer formed by masking, thermal oxidation, or high-concentration doping,
wherein
the nozzle straight portion has the non-wet etching layer for an end portion on a side facing the first surface.

According to the seventh aspect of the invention,
in the nozzle plate, the nozzle straight portion is continuous with an end portion of the nozzle tapered portion on the side facing the second surface.

According to the eighth aspect of the invention,
in the nozzle plate, in a view from the first surface, at least a portion of a ridgeline on a side facing the first surface among ridgelines constituting the nozzle straight portion is substantially in contact with a surface substantially perpendicular to the first surface among surfaces constituting the nozzle tapered portion.

According to the ninth aspect of the invention,
in the nozzle plate,
each of the plurality of nozzle channels includes:
a nozzle tapered portion having a channel area that gradually decreases from the first surface toward the second surface, the channel area being a cross-sectional area perpendicular to a droplet ejection direction; and
a straight communication path that is continuous with a side facing the first surface of the nozzle tapered portion and includes a pair of facing surfaces substantially parallel to each other, and
the nozzle tapered portion and the straight communication path include a {111} plane.

According to the tenth aspect of the invention,
in the nozzle plate, the nozzle tapered portion and the straight communication path are composed of {111} planes.

According to the eleventh aspect of the invention,
in the nozzle plate,
each of the plurality of nozzle channels includes a nozzle straight portion on a side of the nozzle tapered portion facing the second surface.

According to the twelfth aspect of the invention,
the nozzle plate further comprises:
a non-wet etching layer formed by masking, thermal oxidation, or high-concentration doping,
wherein
the nozzle straight portion has the non-wet etching layer for an end portion on a side facing the first surface.

According to the thirteenth aspect of the invention,
in the nozzle plate, the nozzle straight portion is continuous with an end portion of the nozzle tapered portion on the side facing the second surface.

According to the fourteenth aspect of the invention,
in the nozzle plate, in a view from the first surface, at least a portion of a ridgeline on a side facing the first surface among ridgelines constituting the nozzle straight portion is substantially in contact with a surface substantially perpendicular to the first surface among surfaces constituting the nozzle straight communication path.

According to the fifteenth aspect of the invention,
in the nozzle plate,
in a view from the first surface, an absolute value of a difference between a first distance and a second distance is within 0.5 μm, where the first distance is a distance from an intersection line to a farthest point or line on a ridgeline in a first direction parallel to the first surface or the second surface among <100> directions, the intersection line being where two tapered surfaces constituting the nozzle tapered portion intersect when virtually extended, the ridgeline being where a surface constituting the nozzle straight portion intersects with the two tapered surfaces constituting the nozzle tapered portion, and
the second distance is a distance from the intersection line to a farthest point or line on the ridgeline in a second direction parallel to the first surface or the second surface among <100> directions.

According to the sixteenth aspect of the invention,
a droplet ejection head comprises the nozzle plate.

According to the seventeenth aspect of the invention,
a droplet ejection apparatus comprises the droplet ejection head.

According to the eighteenth aspect of the invention,
a method for manufacturing a nozzle plate of a droplet ejection head, comprises:
forming a front mask layer on a first surface of a single-crystal silicon substrate having a {110} surface crystal orientation;
forming an opening pattern that yields an opening of a nozzle channel in the front mask layer; and
performing anisotropic wet etching on the single-crystal silicon substrate from a surface through the opening pattern.

According to the nineteenth aspect of the invention,
in the method for manufacturing the nozzle plate, in the performing, a nozzle tapered portion having a channel area that gradually decreases from the first surface toward a second surface of the single-crystal silicon substrate opposite the first surface is formed, the channel area being a cross-sectional area perpendicular to a droplet ejection direction.

According to the twentieth aspect of the invention,
in the method for manufacturing the nozzle plate,
the forming the front mask layer includes forming a back mask layer on the second surface of the single-crystal silicon substrate, and
the method further comprises:
forming a nozzle pattern that yields a nozzle in the back mask layer; and
forming a nozzle straight portion by performing penetration processing on the single-crystal silicon substrate from a surface through the nozzle pattern by dry etching, the forming the nozzle pattern and the forming the nozzle straight portion being performed after the performing.

According to the twenty-first aspect of the invention,
a method for manufacturing a nozzle plate of a droplet ejection head, comprises:
forming a front mask layer on a first surface of a single-crystal silicon substrate having a {110} surface crystal orientation, and a back mask layer on a second surface of the single-crystal silicon substrate opposite the first surface;
forming a nozzle pattern that yields a nozzle in the back mask layer;
forming a hole that yields a nozzle straight portion by performing dry etching on the single-crystal silicon substrate from a back surface through the nozzle pattern to a middle;
forming a nozzle mask layer on a side wall of the hole;
performing dry etching on the single-crystal silicon substrate from the back surface through the hole;
forming an opening pattern that yields an opening in the front mask layer;
performing dry etching on the single-crystal silicon substrate from a front surface through the opening pattern; and
performing penetration processing on the single-crystal silicon substrate from the front surface and the back surface by anisotropic wet etching to form a nozzle channel that includes a nozzle straight portion, a nozzle tapered portion, and a straight communication path,
wherein
a depth H of a hole formed in the performing dry etching on the single-crystal silicon substrate from the front surface satisfies the following (1):
(1) T−(H+(L/2) tan θ)≥h−(D/2) tan θ, where a thickness of the single-crystal silicon substrate is T, a diameter of the nozzle straight portion is D, a depth of the nozzle straight portion is h, a width of the opening in a <110> direction is L, and an angle formed by the first and second surfaces of the single-crystal silicon substrate and two tapered surfaces of {111} planes constituting the nozzle tapered portion is θ (θ=cos⁻¹(2/√6)≈35.26°.

According to the twenty-second aspect of the invention,
in the method for manufacturing the nozzle plate, when the first surface is set to a (110) plane, a width of the nozzle pattern formed in the forming the nozzle pattern in a [−111] direction and a width of the nozzle pattern in a [1-1-1] direction are wider than a width of the opening pattern formed in the forming the opening pattern in a [−111] direction and a width of the opening pattern in a [1-1-1] direction.

According to the twenty-third aspect of the invention, in the method, a maximum value of a channel area of the nozzle straight portion is less than or equal to the channel area of an end portion of the nozzle tapered portion on the side facing the first surface.

### Advantageous Effects of Invention

According to the nozzle plate, the droplet ejection head, the droplet ejecting apparatus, and the nozzle plate manufacturing method of the present invention, both high density of nozzles and preferable ejection characteristics can be achieved.

### BRIEF DESCRIPTION OF DRAWINGS

FIG. 1 This is a schematic perspective view of a droplet ejecting apparatus according to the present embodiment.

FIG. 2 This is a schematic side cross-sectional view of a droplet ejection head according to the present embodiment.

FIG. 3A This is an enlarged plan view of a nozzle plate illustrating a nozzle channel according to the present embodiment.

FIG. 3B This is a side cross-sectional view of the nozzle plate taken along a line IIIB-IIIB in FIG. 3A.

FIG. 3C This is a perspective cross-sectional view of the nozzle plate illustrating the nozzle channel according to the present embodiment.

FIG. 4 This is an enlarged plan view of a nozzle plate illustrating a nozzle channel according to another embodiment.

FIG. 5 This is a cross-sectional view of a nozzle plate illustrating main steps of a method for manufacturing a nozzle plate according to the first embodiment.

FIG. 6 This is a cross-sectional view of a nozzle plate illustrating main steps of a method for manufacturing a nozzle plate according to a modification example of the first embodiment.

FIG. 7 This is a cross-sectional view of a nozzle plate illustrating main steps of a method for manufacturing a nozzle plate according to the second embodiment.

FIG. 8 This is a cross-sectional view of a nozzle plate illustrating main steps of a method for manufacturing a nozzle plate according to the third embodiment.

FIG. 9 This is a cross-sectional view of a nozzle plate illustrating the relationship of a deep hole formed in the eighth step of the method for manufacturing the nozzle plate according to the third embodiment.

### DESCRIPTION OF EMBODIMENTS

In the following, preferred embodiments of the present invention will be described with reference to the drawings. However, the scope of the invention is not limited to the illustrated examples. In the following description, components having the same function and configuration are denoted by the same reference numerals, and description thereof is omitted.

The Miller index that describes the crystal plane and the direction generally has the following convention, and the present specification also complies with the convention.
(h kl): a specific plane
{h k l}: equivalent planes
[h k l]: a specific direction
<h k l>: equivalent directions

Furthermore, unless otherwise specified, examples in the specification assume the following.

The surface on the bonding side of a wafer surface: the (110) plane

The surface on the ejection side of a wafer surface: the (−1−10) plane

The two tapered surfaces of the four surfaces that constitute a nozzle tapered portion: the (−1−11) plane and the (−1−1−1) plane

The vertical surfaces of the four surfaces that constitute a nozzle tapered portion and the two facing surfaces having longer sides among the four surfaces that constitute a straight communication path: the (−111) plane and the (1−1−1) plane

The two facing surfaces having shorter sides among the four surfaces that constitute the straight communication path: the (1-11) plane and the (−11-1) plane

However, as a matter of course, the present invention is not limited to this description as long as the plane and direction are equivalent to the described contents.

### [Inkjet Recording Apparatus]

First, as a droplet ejecting apparatus according to the present embodiment, an example of the configuration of an inkjet recording apparatus 1 that includes an inkjet head 10, which is a droplet ejection head, is disclosed. In the following description, as shown in the drawings, the conveyance direction of a recording medium PD in the inkjet recording apparatus 1 is referred to as the front-rear direction. The direction perpendicular to the conveyance direction on the conveyance surface of the recording medium PD is referred to as the left-right direction. The direction perpendicular to the front-rear direction and the left-right direction (ink ejection direction) is referred to as the up-down direction. The inkjet head 10 is described with reference to the direction in which the inkjet head 10 is mounted on the inkjet recording apparatus 1.

Unless otherwise specified, the above-mentioned plane orientation of the wafer is followed, and the following is assumed in description.
Up: direction
Down: [−1−10] direction
Left: [−111] direction
Right: [1−1−1] direction
Front: [1−12] direction
Rear: [−11−2] direction

However, as a matter of course, the present invention is not limited to this description as long as the plane and direction are equivalent to the described contents.

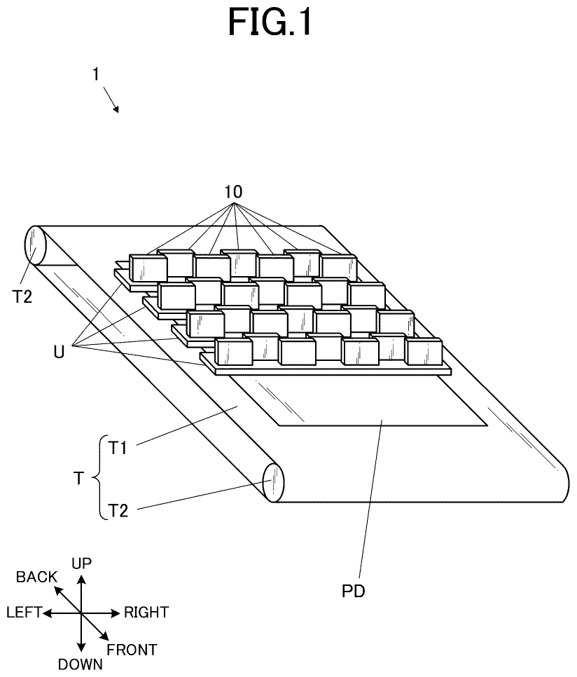

FIG. 1 is a schematic perspective view of the inkjet recording apparatus 1 according to the present embodiment. The inkjet recording apparatus 1 conveys the recording medium PD, such as a sheet, in the front-rear direction through a plurality of units U by a conveyance section T. The conveyance section T includes, for example, a conveyance belt T1 and conveyance rollers T2. In each of the plurality of units U, a plurality of inkjet heads 10 are disposed. Each of the plurality of units U ejects ink of each color from each of the plurality of inkjet heads 10 to print an image on the recording medium PD.

### [Inkjet Head]

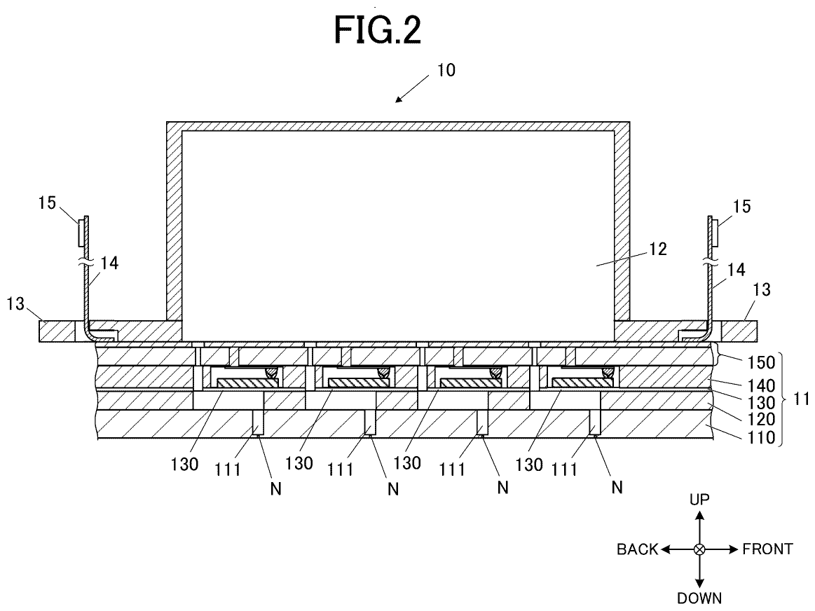

FIG. 2 is a schematic side cross-sectional view of one of the inkjet heads 10 as viewed from the side.

The inkjet head 10 includes a head chip 11, a common ink chamber 12, a support substrate 13, wires 14, and a drive section 15. FIG. 2 shows a cross section of the inkjet head 10 in a plane including four nozzles N.

### [Head Chip]

The head chip 11 is configured to eject ink from the nozzles N. The head chip 11 is formed by stacking a plurality of plate-like substrates (four substrates in FIG. 2). The downmost plate in the head chip 11 is a nozzle plate 110.

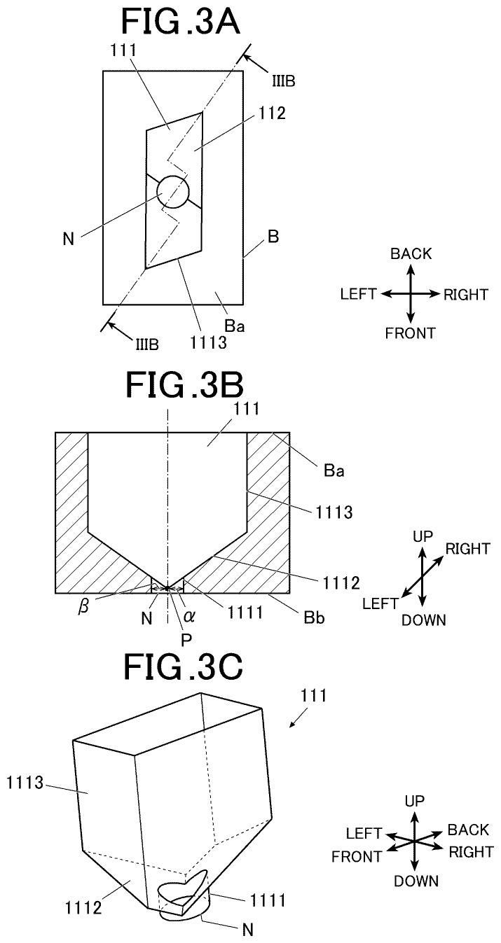

On the bonding surface (first surface) Ba of the nozzle plate 110 (see FIG. 3B), a piezoelectric material plate 120, a vibration plate 130, a spacer substrate 140, and a wiring substrate 150 are bonded and stacked in this order upward, for example. The nozzle plate 110 is provided with a plurality of nozzle channels 111 having a structure according to the present invention. The nozzle plate 110 is capable of ejecting ink substantially vertically to the ejection surface (second surface) Bb (see FIG. 3B) from the nozzles N that are openings of the nozzle channels 111. The ejection surface (second surface) Bb is an exposed surface of the nozzle plate 110 and faces the bonding surface Ba.

The piezoelectric material plate 120, the vibration plate 130, the spacer substrate 140, and the wiring substrate 150 are provided with ink channels that communicate with the nozzles N. The ink channels are opened on the surface of the wiring substrate 150 on the exposed side (upward side). On the exposed surface of the wiring substrate 150, the common ink chamber 12 is provided to cover all the openings.

Ink stored in an ink chamber forming member (not illustrated) of the common ink chamber 12 is supplied to each of the nozzles N from the respective openings of the wiring substrate 150 via the respective ink channels. Then, a pressure chamber provided so as to penetrate the piezoelectric material plate 120 is deformed together with the vibration plate 130 by the displacement (deformation) of a piezoelectric element in a storage section adjacent to the pressure chamber, thereby applying a pressure change to the ink. As a result, the ink is ejected downward from the nozzles N as droplets.

In the head chip 11, it is preferable that the openings of the ink channels on the bonding surface of each plate have similar shapes to each other, and it is more preferable that the openings have the same shape.

The nozzle plate 110 is not limited to the configuration of being bonded to the piezoelectric material plate 120. That is, another plate may be provided between the nozzle plate 110 and the piezoelectric material plate 120. The method of combining the nozzle plate 110 with another plate may be bonding or joining and is not limited thereto.

### [Nozzle Plate]

FIG. 3A is an enlarged plan view illustrating one of the nozzle channels 111 when the nozzle plate 110 is viewed from the side of the bonding surface Ba. FIG. 3B is a cross-sectional view of the nozzle channel 111 taken along a line IIIB-IIIB in FIG. 3A. FIG. 3C is a perspective cross-sectional view of the nozzle channel 111. The nozzle plate 110 is provided, in a single-crystal silicon substrate B, with a plurality of nozzle channels 111 that include nozzles N as illustrated in FIG. 3A to FIG. 3C.

### (Single-Crystal Silicon Substrate)

The single-crystal silicon substrate B is a plate-like member made of single-crystal silicon (Si) with a thickness of, for example, about 50 μm to 725 μm. The crystal orientations of the front and back surfaces of the single-crystal silicon substrate B are {110} planes. Using the single-crystal silicon substrate B as the base material of the nozzle plate 110 makes it possible to process the nozzles N with high precision in the manufacturing process. This allows the nozzles N with little positional error and shape variation to be formed.

### (Nozzle Channel)

Each of the nozzle channels 111 is a through hole that penetrates from the bonding surface Ba, which is the first surface of the single-crystal silicon substrate B, to the ejection surface Bb, which is the second surface. As illustrated in FIG. 3B and FIG. 3C, the nozzle channel 111 is provided with, for example, a nozzle N, a nozzle straight portion 1111, a nozzle tapered portion 1112, and a straight communication path 1113 from the ejection surface Bb toward the bonding surface Ba.

### <Nozzle>

The nozzle N is a cylindrical hole having a circular or polygonal cross-section in the left-right direction. The nozzles N are disposed in a matrix on the side of the ejection surface Bb of the single-crystal silicon substrate B. The side of the nozzle N that faces the bonding surface Ba communicates with the nozzle straight portion 1111. For example, when the cross-sectional shape of the nozzle N in the direction perpendicular to the ejection direction is a perfect circle, the diameter of the opening can be set to about 10 μm to 45 μm.

### <Nozzle Straight Portion>

As illustrated in FIG. 3B, the nozzle straight portion 1111 communicates with the nozzle tapered portion 1112 and is formed so as to be perpendicular to the ejection surface Bb of the single-crystal silicon substrate B.

The channel area of the nozzle straight portion 1111 is formed so as to be less than or equal to the channel area of an end portion of the nozzle tapered portion 1112 on the side facing the ejection surface Bb. Here, the channel area is the cross-sectional area with respect to the ink ejection direction. This configuration increases the resistance applied when the ink is ejected from the nozzle N. As a result, the vibration of the meniscus is suppressed, and the meniscus shape can be more stabilized.

In a case where the single-crystal silicon substrate B includes a non-wet etching layer, the non-wet etching layer may be used for an end portion of the nozzle straight portion 1111 on the side facing the bonding surface Ba.

The non-wet etching layer can be formed by performing, for example, masking, thermal oxidation processing, or high-concentration doping on the single-crystal silicon substrate B. The non-wet etching layer suppresses the progress of anisotropic wet etching in the manufacturing process of the nozzle plate 110 described later. Providing the non-wet etching layer in the single-crystal silicon substrate B thus makes it possible to predefine the length of the nozzle straight portion 1111 in the ejection direction. Therefore, the nozzle straight portion 1111 that has the non-wet etching layer for the end portion on the side facing the bonding surface Ba is a highly precise nozzle straight portion 1111.

For the single-crystal silicon substrate B that includes the non-wet etching layer, a silicon on insulator (SOI) may be used in which an oxide film is provided inside a silicon wafer and a thin silicon layer is formed thereon.

In FIG. 3B and FIG. 3C, the configuration in which the nozzle straight portion 1111 is formed continuously with the end portion of the nozzle tapered portion 1112 on the side facing the ejection surface Bb is illustrated, but the configuration is not limited thereto. However, in a case where the nozzle straight portion 1111 and the nozzle tapered portion 1112 are not continuous with each other and there exits a surface (terrace plane) substantially perpendicular to a surface constituting the nozzle straight portion 1111 at the connection between the two, there is a risk that an injection defect may occur. This is because the ink ejected from the nozzles N entrains air bubbles accumulated on the terrace plane. Therefore, it is preferable that the nozzle straight portion 1111 is formed so as to be continuous with the end portion of the nozzle tapered portion 1112 on the side facing the ejection surface Bb.

Even in a case where the nozzle straight portion 1111 and the nozzle tapered portion 1112 are continuous to each other, when the entire end portion of the nozzle tapered portion 1112 on the side facing the ejection surface Bb is not substantially continuous to the end portion of the nozzle straight portion 1111 on the side facing the bonding surface Ba, there is a risk that air bubbles may remain on a terrace ridgeline. This is because a straight line (terrace ridgeline) perpendicular to the nozzle straight portion 1111 is formed at a place where the nozzle tapered portions 1112 and 1112 intersect with each other. Therefore, it is more preferable that the nozzle straight portion 1111 is formed so as to be continuous with the entire end portion of the nozzle tapered portion 1112 on the side facing the ejection surface Bb.

### <Nozzle Tapered Portion>

The nozzle tapered portion 1112 includes two surfaces (the (−1−1−1) plane and the (−1−11) plane) whose crystal planes are {111} planes. The nozzle tapered portion 1112 has a taper at a substantially constant angle such that the channel area gradually decreases from the bonding surface Ba toward the ejection surface Bb. Providing the nozzle tapered portion 1112 in the nozzle channel 111 makes it possible to stabilize the meniscus shape and ink ejection even when the meniscus of ink has retreated to the depth of the nozzle channel 111 due to high-speed driving.

It is preferable that the nozzle straight portion 1111 and the nozzle tapered portion 1112 have less eccentricity. Specifically, as illustrated in FIG. 3B, when the two surfaces constituting the nozzle tapered portion 1112 are virtually extended, the virtual intersection line is denoted as P; the distances from the intersection line P to the farthest point or line on a ridgeline, where the outer diameter of the nozzle N intersects with the nozzle tapered portion 1112 having the two surfaces, in the directions parallel to the bonding surface Ba or the ejection surface Bb among the <110> directions are denoted as a and B; then, it is preferable that the nozzle tapered portion 1112 is formed so that the absolute value of the difference between a and B is within 0.5 μm. Here, the directions parallel to the bonding surface Ba or the ejection surface Bb are the direction and the [00−1] direction when the bonding surface Ba is the (110) plane.

### <Straight Communication Path>

The straight communication path 1113 includes four surfaces (the (−111) plane, the (1−1−1) plane, the (1−1−1) plane, and the (−11−1) plane) whose crystal planes are {111} planes. The straight communication path 1113 is provided from an end portion of the nozzle tapered portion 1112 on the side facing the bonding surface Ba to the bonding surface Ba.

As illustrated in FIG. 3A, the straight communication path 1113 includes two pairs of facing surfaces that are substantially parallel to each other. The straight communication path 1113 is configured such that, among the sides where the surfaces constituting the straight communication path 1113 intersect with the bonding surface Ba, the side length of one pair of facing surfaces is longer than the side length of the other surfaces. That is, the sides where the bonding surface Ba and the surfaces constituting the straight communication path 1113 intersect can be made into in an elongated, substantially parallelogram shape. When the shape of the opening of the nozzle channel 111 on the bonding surface Ba is a substantially parallelogram shape, that is, an elongated shape, the density of the nozzles N in the nozzle plate 110 is increased compared to when the shape is a square shape.

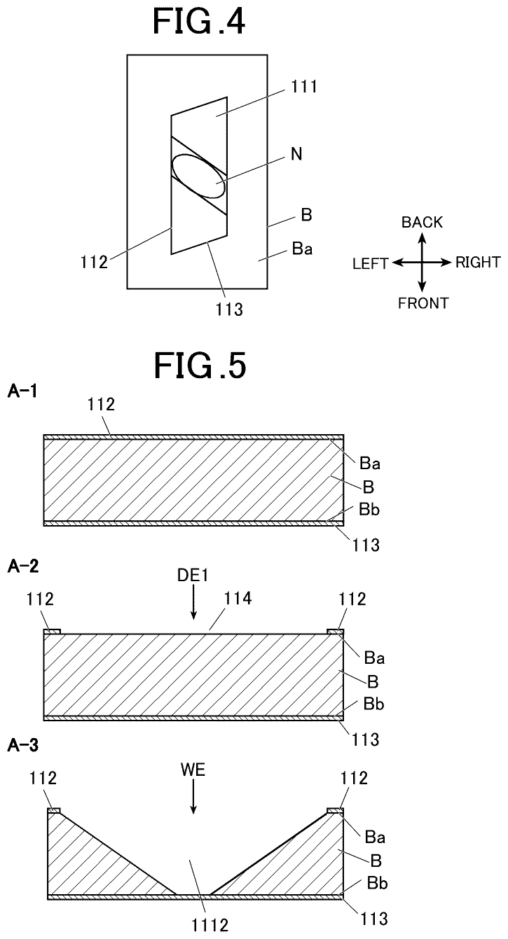

As illustrated in FIG. 4, it is preferable that the nozzle straight portion 1111 is provided such that, in a top view as viewed from the side of the bonding surface Ba, at least a portion of the ridgelines of the nozzle straight portion 1111 on the side facing the bonding surface Ba among the ridgelines thereof is substantially in contact with a surface that is substantially perpendicular to the bonding surface Ba among the surfaces constituting the straight communication path 1113. For such a nozzle channel 111, the eccentricity falls within a very small range, resulting in excellent injection stability.

In FIG. 3A to FIG. 3C, a case where all of the two surfaces constituting the nozzle tapered portion 1112 and the four surfaces constituting the straight communication path 1113 are {111} planes is exemplified, but the present invention is not limited thereto. That is, in the manufacturing process described later, the nozzle channel 111 including {111} planes and a plane of another orientation may be formed by stopping anisotropic wet etching in the middle.

In FIG. 3A to FIG. 3C, the nozzle channel 111 including the nozzle straight portion 1111, the nozzle tapered portion 1112, and the straight communication path 1113 is illustrated, but these are not essential components. It is only required that the nozzle channel 111 is at least a through hole including the nozzle N.

Furthermore, in the above description, the nozzle plate 110 that is attached to the inkjet head 10 to eject ink is exemplified. However, the liquid ejected from the nozzle plate 110 is not limited to ink.

### Advantageous Effects of Invention

As described above, the nozzle plate 110 according to the present embodiment includes, in the single-crystal silicon substrate B, a plurality of nozzle channels 111 that penetrates the nozzle plate 110 and ejects liquid droplets. The single-crystal silicon substrate B includes the bonding surface Ba and the ejection surface Bb that faces the bonding surface Ba. Here, the bonding surface Ba and the ejection surface Bb are on {110} planes, and the nozzles N are formed on the ejection surface Bb. This configuration allows the shape of the cross section of the nozzle channel 111 on the side facing the bonding surface Ba to be a substantially parallelogram shape, that is, an elongated shape. This makes it possible for the nozzles N to be arranged at a higher density in the nozzle plate 110 than in a case where the cross section has a square shape.

The nozzle channel 111 includes surfaces of {111} planes. According to this configuration, the nozzle channel 111 becomes a stable shape.

The nozzle channel 111 includes the nozzle tapered portion 1112 in which the channel area, which is the cross-sectional area perpendicular to the droplet ejection direction, gradually decreases from the bonding surface Ba toward the ejection surface Bb. This configuration makes it possible to stabilize the meniscus shape and the ink ejection even when the meniscus of ink has retreated to the depth of the nozzle channel 111 due to high-speed driving.

The nozzle channel 111 includes the nozzle straight portion 1111 that is provided on the side facing the ejection surface Bb of the nozzle tapered portion 1112 and has the channel area less than or equal to the channel area of the nozzle tapered portion 1112. This configuration increases the resistance during droplet ejection, suppressing the vibration of the meniscus and further stabilizing the meniscus shape, thereby improving the ejection stability.

The nozzle plate 110 includes a non-wet etching layer formed by masking, thermal oxidation, or high-concentration doping. This allows the nozzle straight portion 1111 to have the non-wet etching layer for the end portion on the side facing the bonding surface Ba. According to this configuration, the location of the nozzle straight portion 1111 is defined by the non-wet etching layer, resulting in high precision in the nozzle straight portion 1111.

The nozzle straight portion 1111 can be provided continuously with the end portion of the nozzle tapered portion 1112 on the side facing the second surface. According to this configuration, the nozzle channel 111 has no terrace plane. This prevents the ink ejected from the nozzles N from entraining air bubbles accumulated on the terrace plane, thereby preventing an injection defect.

In a top view as viewed from the side of the bonding surface Ba, among the ridgelines constituting the nozzle straight portion 1111, at least a portion of the ridgelines on the side facing the bonding surface Ba is substantially in contact with a surface substantially perpendicular to the bonding surface Ba among the surfaces constituting the nozzle tapered portion 1112 or the straight communication path 1113. The surfaces substantially perpendicular to the bonding surface Ba are, for example, the (−111) plane and the (1−1−1) plane when the bonding surface Ba is the (110) plane. According to this configuration, the nozzle channel 111 has less eccentricity in the front-rear direction in FIG. 4.

### Method for Manufacturing Nozzle Plate

### First Embodiment

Next, the method for manufacturing the nozzle plate 110 according to the first embodiment will be described with reference to FIG. 5. The method for manufacturing the nozzle plate according to the first embodiment is to manufacture the nozzle plate 110 of the droplet ejection head 10. The manufacturing method includes steps A-1 to A-3 shown in FIG. 5 to manufacture the nozzle plate 110 in which the nozzle channels 111 including at least the nozzles N are formed.

### (Step A-1)

First, in the step A-1 (first step), a front mask layer 112 and a back mask layer 113 are uniformly formed on the bonding surface (first surface) Ba and the ejection surface (second surface) Bb, respectively, of a single-crystal silicon substrate B whose surfaces have the crystal orientations of {110} planes. Here, the first surface is the (110) plane, and the second surface is the (−1−1 0) plane. Hereinafter, when the front mask layer 112 and the back mask layer 113 are not particularly distinguished from each other, the front mask layer 112 and the back mask layer 113 are collectively referred to as “mask layers.”

### <Mask Layer>

For the material of the mask layers, for example, an oxide such as silicon oxide (SiO₂), metal plating with aluminum (Al), chromium (Cr), or the like, a resin, or the like can be used. However, the material of the mask layers is not particularly limited as long as the material can stop the progress of etching during the anisotropic wet etching described later and is not removed by etching.

The thickness (length in the up-down direction) of the mask layers is not particularly limited. However, the thickness of the mask layers is preferably 0.1 to 50 μm, particularly preferably 0.5 to 20 μm. This is because the etching stop effect is enhanced when the thickness of the mask layers is 0.5 μm or more, and the formation of the mask layers is facilitated when the thickness of the mask layer is 20 μm or less. However, when the mask layers are formed by the above-described thermal oxidation, the thickness is preferably set to 1 to 5 μm.

Each of the mask layers may have a single-layer structure as shown in FIG. 5 or a multi-layer structure.

### (Step A-2)

Next, in the step A-2 (second step), an opening pattern 114 that yields the openings of the nozzle channels 111 is formed in the front mask layer 112. Specifically, a resist pattern is first formed on the front mask layer 112 by a well-known photolithography technique.

### <Resist Pattern>

For the formation of the resist pattern, a positive photoresist or a negative photoresist can be used. For the positive photoresist and the negative photoresist, known materials can be used. For example, ZPN-1150-90 manufactured by Zeon Corporation can be used for the negative photoresist. For the positive photoresist, OFPR-800 LB or OEBR-CAP112PM manufactured by Tokyo Ohka Kogyo Co., Ltd. can be used.

A resist layer is formed by coating to a predetermined thickness using a spin coater or the like. After that, a pre-baking process is performed under conditions of, for example, 110° C. and 90 seconds.

To improve adhesion, HMDS treatment may be performed before resist coating. The HMDS treatment refers to an organic material called hexamethyldisilazane. For example, hexamethyldisilazane manufactured by Tokyo Ohka Kogyo Co., Ltd (OAP) or the like can be used for the HMDS treatment. Similarly to the resist coating, a spin coater may be used for coating. Exposure to hexamethyldisilazane vapor is also expected to improve adhesion.

After the formation of the resist layer, the resist layer is exposed with an aligner or the like using a predetermined mask. For example, in the case of a contact aligner, the exposure is performed with an amount of light of about 50 mJ/cm². After that, the exposed portion of the resist layer is removed by immersion in a developer, thereby forming a resist pattern on the front mask layer 112. Here, the immersion in a developer means, for example, immersion in NMD-3 manufactured by Tokyo Ohka Kogyo Co., Ltd. for 60 seconds to 90 seconds.

After the formation of the resist pattern, the opening pattern 114 is formed by dry etching (DE1) the front mask layer 112 using the resist pattern as a mask. After the formation of the opening pattern 114, the resist pattern is removed.

### <Dry Etching>

A dry etching apparatus is used for the dry etching (DE1). Examples of the dry etching apparatus include a reactive ion etching (RIE) apparatus and an inductively coupled plasma (ICP) RIE etching apparatus, which is a dry etching apparatus employing an inductively coupled method as a discharge method. For the process gas, trifluoromethane (CHF₃), tetrafluoromethane (CF₄), or the like is used.

As an example, the opening pattern 114 can be formed by etching for a predetermined time using RIE 100C, which is a dry etching apparatus manufactured by SAMCO Inc., under the conditions of a CHF₃ gas flow rate of 80 sccm, a pressure of 3 Pa, and an RF power of 90 W.

The shape of the opening pattern 114 is not particularly limited. However, when anisotropic wet etching (WE) is performed to the end in the step A-3 described below, the opening formed by the sides where the four surfaces constituting each nozzle tapered portion 1112 intersect the bonding surface Ba has a substantially parallelogram shape that circumscribes the opening pattern 114. Therefore, from the viewpoint of improving the quality and production efficiency of the nozzle plate 110, it is preferable that the shape of the opening pattern 114 is also a substantially parallelogram shape following these surface orientations. The four surfaces constituting each nozzle tapered portion 1112 are the (−1−1−1) plane, the (−1−11) plane, the (−111) plane, and the (1−1−1) plane, and the bonding surface Ba is the (110) plane.

### <Removal of Resist Pattern>

As for the method of removing the resist pattern, the resist pattern can be removed by, for example, a wet process using acetone or an acid solution, or a dry process using oxygen plasma.

### (Step A-3)

Finally, in the step A-3 (third step), the anisotropic wet etching (WE) is performed on the opening pattern 114 at least from the side of the bonding surface Ba of the single-crystal silicon substrate B to form the nozzle channels 111 that include the nozzle tapered portions 1112.

### <Anisotropic Wet Etching>

For the anisotropic wet etching, an alkaline aqueous solution such as potassium hydroxide (KOH), tetramethylammonium hydroxide (TMAH), or ethylenediamine pyrocatechol (EDP) is used.

### Advantageous Effects of Invention

With the method of manufacturing the nozzle plate 110 according to the first embodiment of the present invention as described above, it is possible to form the nozzle channels 111 that include the nozzle tapered portions 1112 having very stable shapes formed on the {111} planes.

In addition, in the single-crystal silicon substrate B whose crystal orientation of the front surface is a {110} plane, the surface formed when the anisotropic wet etching is performed from the front surface to the end has an extremely lower etching rate than the other surfaces, and thus becomes a {111} plane on which a so-called “etching stop” occurs. This allows, in managing conditions of anisotropic wet etching in which production variations are generally likely to occur, production management to be performed with a margin enough to absorb the production variations.

In a case where the nozzle channel 111 that is a through hole is formed by performing anisotropic wet etching on the single-crystal silicon substrate B from the bonding surface Ba, the opening of the nozzle channel 111 on the side of the bonding surface Ba can be formed in an elongated, substantially parallelogram shape, that is, in an elongated shape. Here, the crystal orientation of the front surface of the single-crystal silicon substrate B is a {110} plane. This makes it possible to increase the density of the nozzles N in the nozzle plate 110.

In the step A-1, the mask layers are formed on both surfaces of the single-crystal silicon substrate B, but the present invention is not limited thereto. Specifically, for example, when anisotropic wet etching is performed by immersing the single-crystal silicon substrate B in an etching solution, it is necessary to form the back mask layer 113 on the ejection surface Bb. However, when anisotropic wet etching is performed only on the bonding surface Ba, the back mask layer 113 may not be provided.

When the back mask layer 113 is formed on the ejection surface Bb, it is, of course, necessary to remove at least the back mask layer(s) 113 covering the nozzles N after the step A-3. However, whether to remove the other back mask layer(s) 113 and/or the front mask layer(s) 112 is optional. When the mask layers are formed of, for example, SiO₂, the mask layers can be removed with hydrofluoric acid.

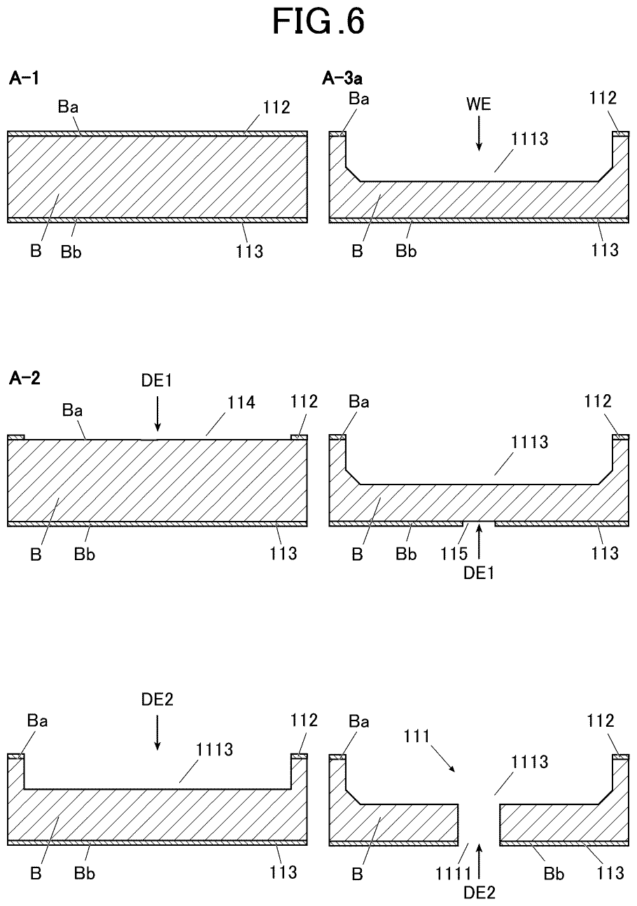

The nozzle tapered portions 1112 are formed by the anisotropic wet etching (WE) in the step A-3, but the present invention is not limited thereto. For example, as shown in FIG. 6, after the step A-2, the straight communication paths 1113 may be formed by dry etching (DE2) the single-crystal silicon substrate B through the opening pattern 114; next, in the step A-3a (third step), after the time is controlled so that the anisotropic wet etching (WE) is stopped midway, the nozzle pattern 115 that yields the nozzles N may be formed by dry etching (DE1) the ejection surface Bb; then, the single-crystal silicon substrate B with the nozzle pattern 115 may be dry etched (DE2) to provide through holes, thereby forming the nozzle channels 111. The dry etching (DE2) may be performed using an ICP-RIE etching apparatus that employs an inductively coupled method (inductively coupled plasma) as a discharge method.

The nozzle channels 111 that include the nozzle tapered portions 1112 and the straight communication paths 1113 may be provided by forming deep holes by dry etching (DE2) using a Si deep etching apparatus or the like after forming the opening pattern 114 in the step A-2, and performing anisotropic wet etching (WE) on the deep holes in the step A-3.

### Second Embodiment

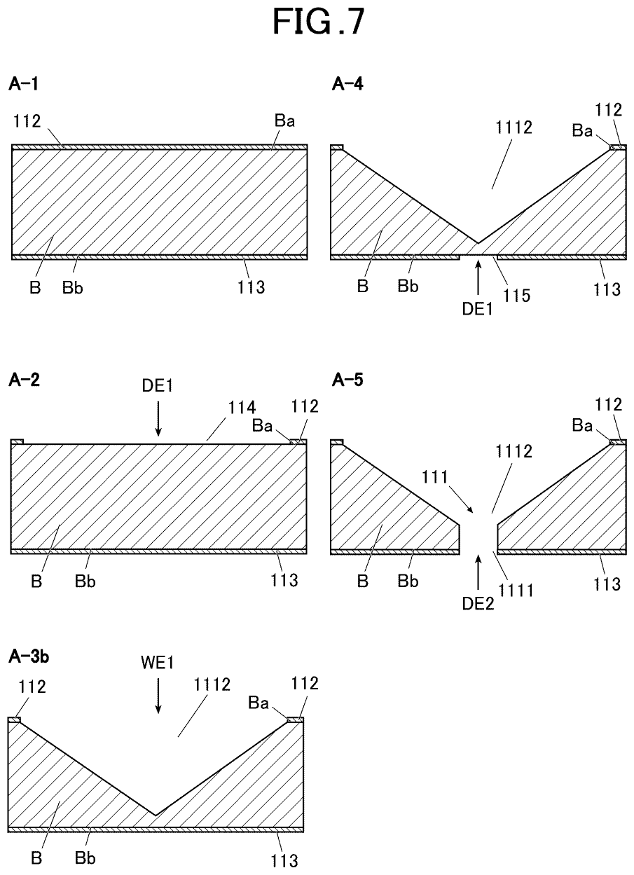

Next, the method for manufacturing the nozzle plate 110 according to the second embodiment will be described with reference to FIG. 7. In the method of manufacturing the nozzle plate 110 according to the second embodiment, steps A-3b to A-5 are performed after the step A-2 of the method of manufacturing the nozzle plate 110 according to the first embodiment. Therefore, the detailed description of the steps A-1 and A-2 is omitted.

### (Step A-4)

After deep holes are formed by performing anisotropic wet etching (WE) in the step A-3b (third step), the nozzle pattern 115 that yields the nozzles N is formed in the back mask layer 113 in the step A-4 (fourth step).

Specifically, in the step A-3b according to the second embodiment, the anisotropic wet etching (WE) is performed until the etching stops on the surfaces constituting each nozzle tapered portion 1112, which are {111} planes formed by the anisotropic wet etching (WE). The method of forming the nozzle pattern 115 in the step A-4 is the same as the method of forming the opening pattern 114 in the step A-2.

### (Step A-5)

In the step A-5 (fifth step), dry etching (DE2) is performed on the nozzle pattern 115 provided in the step A-4. Then, the holes that yield the nozzle straight portions 1111 are made to communicate with the nozzle tapered portions 1112 provided in the step A-3b to form the nozzle channels 111 that include the nozzle straight portions 1111 and the nozzle tapered portions 1112.

### Advantageous Effects of Invention

According to the method of manufacturing the nozzle plate 110 according to the second embodiment of the present invention as described above, it is possible to form the nozzle channels 111 that include the nozzle straight portions 1111 and the nozzle tapered portions 1112 having very stable shapes formed on {111} planes.

The etching may be stopped in the step A-3b by providing the single-crystal silicon substrate B with a non-wet etching layer. In order to obtain the single-crystal silicon substrate B provided with a non-wet etching layer, masking, thermal oxidation processing, high concentration doping, or the like is performed on the single-crystal silicon substrate B, or SOI is used for the single-crystal silicon substrate B. This allows the heights of the nozzle straight portions 1111 formed in the step A-5 to be uniquely determined, making it possible to form the nozzle straight portions 1111 with higher precision.

When the single-crystal silicon substrate B that includes a non-wet etching layer is used for the nozzle plate 110, anisotropic wet etching (WE) may be performed from both the bonding surface Ba and the ejection surface Bb. Specifically, after the step A-2, deep etching is performed by dry etching (DE2); then, the steps A-4 and A-5 are performed; and after the step A-5, as the step A-3b, anisotropic wet etching (WE) is performed from both the bonding surface Ba and the ejection surface Bb. This makes it possible to form the nozzle channels 111 that include the nozzle straight portions 1111 in the non-wet etching layers, and the straight communication paths 1113 and nozzle tapered portions 1112.

### Third Embodiment

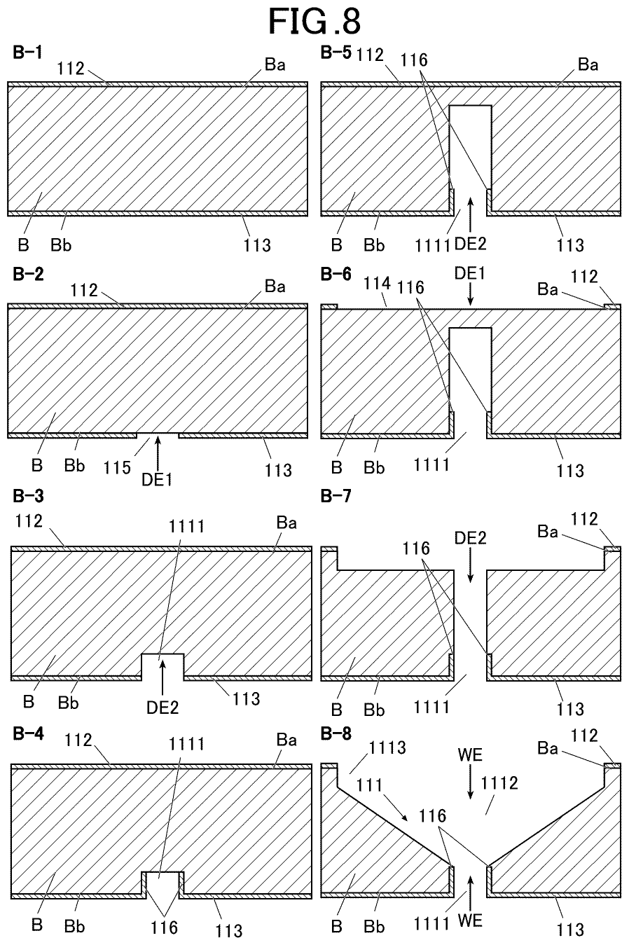

Next, the method for manufacturing the nozzle plate according to the third embodiment of the present invention and the nozzle plate manufactured by the method will be described with reference to FIG. 8. The method of manufacturing the nozzle plate 110 according to the third embodiment includes steps B-1 to B-8 shown in FIG. 8. In the following description, the detailed description of the content that overlaps with the steps of manufacturing the nozzle plate according to the first embodiment and the second embodiment is omitted.

### (Step B-1, Step B-2)

First, in the step B-1 (first step), the front mask layer 112 and the back mask layer 113 are uniformly formed on the bonding surface Ba (the (110) plane) and the ejection surface Bb (the (−1−10) plane), respectively, of the single-crystal silicon substrate B whose surfaces have the crystal orientation of {110} planes. In the step B-2 (second step), the nozzle pattern 115 that yields the nozzles N is formed in the back mask layer 113.

### (Step B-3)

In the step B-3 (third step), each of the nozzle straight portions 1111 is formed by dry etching (DE2) the single crystal silicon substrate B through the nozzle pattern 115 by a predetermined length of the nozzle straight portion 1111.

### (Step B-4)

In the step B-4 (fourth step), nozzle mask layers 116 are formed along the inner surfaces of the nozzle straight portion 1111. The material and the formation method of the nozzle mask layers 116 are the same as the material and the formation method of the mask layers in the Step A-1.

After that, the nozzle mask layer 116 formed at the bottom of the nozzle straight portion 1111 is removed. The nozzle mask layer 116 at the bottom of the nozzle straight portion 1111 can be removed by dry etching using an RIE apparatus or the like. However, dry etching using the RIE apparatus is difficult to remove the nozzle mask layers 116 formed on the side surfaces compared to the nozzle mask layer 116 formed at the bottom, due to the verticality of an etchant. Therefore, the nozzle mask layer 116 at the bottom is etched first while the nozzle mask layers 116 remain on the side surfaces.

The dry etching conditions in the step B-4 may be set to a low pressure or a high bias so that the nozzle mask layers 116 on the side surfaces are less likely to be etched.

### (Step B-5)

In the step B-5 (fifth step), each of the nozzle straight portions 1111 is further deep-etched by dry etching (DE2).

### (Step B-6, Step B-7)

In the step B-6 (sixth step), the opening pattern 114 that yields the openings of the nozzle channels 111 is formed in the front mask layer 112. In the step B-7 (seventh step), holes that yield the straight communication paths 1113 are provided by dry etching (DE2) the single-crystal silicon substrate B through the opening pattern 114.

In the step B-7, as illustrated in FIG. 8, it is preferable that dry etching (DE2) is performed until all the nozzle channels 111 communicate with the holes provided in the step B-5 to penetrate the single-crystal silicon substrate B. In the case where the through holes are provided in the step B-7, hydrogen gas, which is generated when anisotropic wet etching (WE) is performed in the step B-8 (eighth step) described later, is uniformly and efficiently released, resulting in uniform etching progress. As a result, shape variation is less likely to occur in the nozzle channels 111. However, it is not essential to penetrate the single-crystal silicon substrate B in the step B-7. In a case where the single-crystal silicon substrate B is not penetrated in the step B-7, it is possible, by digging up to just before penetration, to shorten the time for penetration by wet etching in the wet etching process of the step B-8.

### (Step B-8)

In the step B-8, anisotropic wet etching (WE) is performed from both sides of the bonding surface Ba and the ejection surface Bb to enlarge the holes provided in the step B-5 and the holes provided in the step B-7, thereby forming the nozzle tapered portions 1112. In this step, since the nozzle straight portions 1111 are protected by the nozzle mask layers 116, the progress of etching is suppressed and the nozzle straight portions 106 remain.

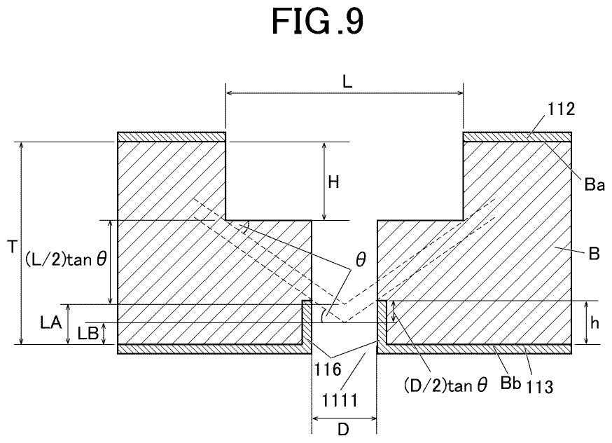

As shown in FIG. 9, the depth H of each of the holes formed in the step B-7 of the method of manufacturing the nozzle plate 110 according to the third embodiment satisfies the following: T−(H+(L/2) tan θ)≥h−(D/2) tan θ. In this equation, T is the thickness of the single-crystal silicon substrate B when the bonding surface Ba is the (110) plane and the ejection surface Bb is the (−1−10) plane; D is the width of each of the nozzle straight portions 1111 in the direction and the direction; H is the depth (length in the ejection direction) of each of the nozzle straight portions 1111. L is the width of the opening pattern 114 in the direction and the [00−1] direction. θ is the angle between the (−1−10) plane and the (−1−1−1) plane of the single-crystal silicon substrate B, i.e., θ=cos⁻¹(2/√6)≈35.26 degrees. In FIG. 9, the left hand side of the equation, T−(H+(L/2) tan θ), and the right hand side of the equation, h−(D/2) tan θ, are illustrated as LA and LB, respectively.

### Advantageous Effects of Invention

According to the method of manufacturing the nozzle plate 110 according to the third embodiment as described above, the nozzle mask layers 116 formed in the nozzle channels 111 suppress the progress of etching during anisotropic wet etching (WE). This makes it possible to form, in each of the nozzle channels 111, the nozzle straight portion 1111 having a desired length.

In the step B-8, the etching progresses from both the end portion of each nozzle straight portion 1111 on the side facing the bonding surface Ba and the end portion of each hole provided in the step B-7 on the side facing ejection surface Bb. However, by setting the depth H of each hole formed in the step B-7 so as to satisfy the above equation, the two tapered surfaces of each nozzle tapered portion 1112 to be finally formed are always formed continuously from the side facing the bonding surface Ba of each nozzle straight portion 1111. This makes it possible to manufacture the nozzle straight portion 1111 and the nozzle tapered portion 1112 without misregistration. This allows for the nozzle channel 111 in which the eccentricity is small, the symmetry of the ink flow is maintained, and the ejection angle is stable.

In the nozzle channels 111 in their final form, etching is stopped on {111} planes that circumscribe the holes formed in the step B-7 and the ridgelines of the nozzle straight portions 1111 on the side facing the bonding surface Ba. This prevents misregistration or step difference between the nozzle tapered portions 1112 and the straight communication paths 1113, resulting in stable nozzle channels 111.

In the dry etching process, precise control is difficult due to dry etching conditions such as concentration distribution of an etchant and voltage distribution, and a manufacturing error is likely to occur. However, as long as the above equation is satisfied, the surfaces constituting each nozzle tapered portion 1112 formed in the step B-8 are formed continuously from the end portions of the surfaces constituting each nozzle straight portion 1111 on the side facing the bonding surface Ba. This makes it possible to set the depth H of each hole formed in the step B-7 to be slightly negative with a margin from the final, desired depth of each straight communication path 1113, thereby reducing the manufacturing error caused in this process. This allows for manufacturing the nozzle plate 110 with stable ejection characteristics.

It is preferable that the widths of the nozzle pattern 115 in the [−111] direction and the [1−1−1] direction are wider than the widths of the opening pattern 114 in the [−111] direction and the [1−1−1] direction. Here, the nozzle pattern 115 is formed in the step B-2 and the opening pattern 114 is formed in the step B-6.

In a case where this configuration is satisfied, when the anisotropic wet etching is performed to the end in the step B-8, the four surfaces constituting each straight communication path 1113 eventually reach {111} planes (the (−111) plane, the (1−1−1) plane, the (1−11) plane, and the (−11−1) plane) that circumscribe the outermost diameter of the opening pattern 114 or the nozzle pattern 115. As a result, at least a portion of the ridgelines on the side facing the bonding surface Ba of the surfaces constituting each nozzle straight portion 1111 substantially comes in contact with the (−111) plane and the (1−1−1) plane among the surfaces constituting each straight communication path 1113. This makes it possible to provide the nozzle channels 111 with less eccentricity in the [−111] direction and the [1−1−1] direction.

In the above description, the steps B-6 and B-7 in which the holes that yield the straight communication paths 1113 are provided from the bonding surface Ba are performed after the steps B-3 to B-5 in which the nozzle straight portions 1111 are provided from the ejection surface Bb, but the present invention is not limited thereto. That is, the holes that yield the straight communication paths 1113 may be provided before the nozzle straight portions 1111.

After the step B-8, removal processing may be performed on the bonding surface Ba of the single-crystal silicon substrate B by etching, grinding, or polishing so that the thickness of the nozzle plate 110 and the depth of each straight communication path 1113 are adjusted to desired dimensions. A process of removing the mask layers including the nozzle mask layers 116 may be performed.

In the manufacturing method according to each embodiment, at least one protective film may be formed in order to use the nozzle plate 110 for a long period of time. In this case, a step of forming a protective film that covers at least a portion of the surfaces including the inside of the nozzle channel 111 is performed after the final step of each embodiment.

For the protective film, a material that does not dissolve upon contact with the ink is used. The protective film includes, for example, a metal oxide film such as tantalum pentoxide, hafnium oxide, niobium oxide, titanium oxide, and zirconium oxide. Alternatively, the protective film may be a metal silicate film containing silicon in a metal oxide film such as tantalum silicate, hafnium silicate, niobium silicate, titanium silicate, or zirconium silicate. Furthermore, for the protective film, a silicon carbide (SiC) film, a diamond-like carbon (DLC) film, or the material used for forming the mask layers may be used. For the protective film, an organic film such as polyimide, polyamide, or parylene may also be used. The thickness of the protective film is not particularly limited, but may be set to, for example, 0.05 μm to 20 μm.

### EXAMPLES

Next, with respect to Examples and Comparative Examples of the present invention, the results of evaluating preferred configurations will be described. Hereinafter, the present invention will be specifically described with reference to Examples, but the present invention is not limited thereto.

### [Sample Preparation]

The nozzle plate 110 having 1280 nozzle channels 111 formed as in each of the following Examples and Comparative Examples was manufactured. Next, the piezoelectric material plate 120 and the nozzle plate 110 were bonded to form the inkjet head 10. In the piezoelectric material plate 120, the cross-sectional shape of the ink channel in the left-right direction is the same as the cross-sectional shape of the bonding surface Ba of the nozzle plate 110 in the left-right direction. Then, the inkjet heads 10 were mounted on the inkjet recording apparatus 1.

### Example 1

The nozzle channels 111 were formed by the following steps A-1 to A-3. Step A-1: The front mask layer 112 and the back mask layer 113, each with the thickness of 1 μm, were formed by thermal oxidation on the single-crystal silicon substrate B with the thickness of 50 μm whose surfaces have the crystal orientations of the (110) plane and the (−1−10) plane. Step A-2: Using a positive photoresist, a substantially parallelogram pattern was formed on the front mask layer 112. The substantially parallelogram pattern has the base of 130 μm, the height of 50 μm, and the angles between the sides matching the angles between the (−111) plane, (1−1−1) plane, (1−11) plane, and (−11−1) plane. Next, dry etching (DE1) was performed using an RIE apparatus to form the opening pattern 114. For the etching gas, CHF₃ gas was used. After the dry etching, the photoresist was removed by immersion in acetone. Step A-3: Anisotropic wet etching (WE) was performed by immersion in a 40 wt % KOH solution at 80° C. for 35 minutes to form the nozzle tapered portions 1112 having {111} planes. The mask layers were removed with hydrofluoric acid after the step A-3.

### Example 2

The nozzle channels 111 were formed by the following steps A-1 to A-5. Step A-1: The front mask layer 112 and the back mask layer 113, each with the thickness of 1 μm, were formed by thermal oxidation on the single-crystal silicon substrate B with the thickness of 83 μm whose surfaces have the crystal orientations of the (110) plane and the (−1−10) plane. Step A-2: Using a positive photoresist, a substantially parallelogram pattern was formed on the front mask layer 112. The substantially parallelogram pattern has the base of 130 μm, the height of 50 μm, and the angles between the sides matching the angles between the (−111) plane, (1−1−1) plane, (1−11) plane, and (−11−1) plane. Next, dry etching (DE1) was performed using an RIE apparatus to form the opening pattern 114. Step A-3: Anisotropic wet etching (WE) was performed for 35 minutes under the same conditions as in Example 1 to form the nozzle tapered portions 1112 having {111} planes. Step A-4: Using the RIE apparatus, the pattern formed on the back mask layer 113 was dry etched (DE1) to form the nozzle pattern 115 having a perfectly circular shape with the diameter φ of 30 μm. For the etching gas, CHF₃ gas was used. Step A-5: Using a Si deep etching apparatus, the single-crystal silicon substrate B with the nozzle pattern 115 was dry etched (DE2) by the Bosch process to communicate with the nozzle tapered portions 1112 provided in the step A-3. As a result, the nozzle straight portions 1111 each having the depth of 40.6 μm were formed. For the etching gas, SF₆ and C₄F₈ gases were used. The mask layers were removed with hydrofluoric acid after the step A-5.

### Example 3

The nozzle channels 111 were formed by the following steps A-1 to A-5. Step A-1: A thick SiO₂ film with the thickness of 10 μm was formed by thermal oxidation as a non-wet etching layer on the ejection surface Bb of the single-crystal silicon substrate B, whose surfaces have the crystal orientations of the (110) plane and the (−1−10) plane. The total thickness was set to 50 μm. The front mask layer 112 having the thickness of 1 μm was formed on the bonding surface Ba by thermal oxidation. The back mask layer 113 was formed on the non-wet etching layer of the ejection surface Bb by using a positive photoresist. Step A-2: Using a positive photoresist, a substantially parallelogram pattern was formed on the front mask layer 112. The substantially parallelogram pattern has the base of 130 μm, the height of 50 μm, and the angles between the sides matching the angles between the (−111) plane, (1−1−1) plane, (1−11) plane, and (−11−1) plane. Next, dry etching (DE1) was performed using an RIE apparatus to form the opening pattern 114. Step A-3: Anisotropic wet etching (WE) was performed for 35 minutes under the same conditions as in Example 1 to form the nozzle tapered portions 1112 having {111} planes. Step A-4: Using the RIE apparatus, the pattern formed on the back mask layer 113 was dry etched (DE1) to form the nozzle pattern 115 having a perfectly circular shape with the diameter φ of 30 μm. Step A-5: Dry etching (DE2) was performed using the RIE apparatus to form the nozzle straight portions 1111 having the depth of 10 μm.

### Example 4

The nozzle channels 111 were formed by the following steps A-1 to A-5. Step A-1: A thick SiO₂ film with the thickness of 10 μm was formed by thermal oxidation as a non-wet etching layer on the ejection surface Bb of the single-crystal silicon substrate B, whose surfaces have the crystal orientations of the (110) plane and the (−1−10) plane. The total thickness was set to 50 μm. The front mask layer 112 having the thickness of 1 μm was formed on the bonding surface Ba by thermal oxidation. The back mask layer 113 was formed on the non-wet etching layer of the ejection surface Bb by using a positive photoresist. Step A-2: Using a positive photoresist, a substantially parallelogram pattern was formed on the front mask layer 112. The substantially parallelogram pattern has the base of 130 μm and the height of 15 μm, which is narrower than the diameter φ of 30 μm of the nozzle pattern 115 to be formed in the subsequent step A-4, and the angles between the sides matching the angles between the (−111) plane, (1−1−1) plane, (1−11) plane, and (−11−1) plane. After that, the steps A-4 and A-5 were performed to form through holes. A-3 process: Anisotropic wet etching (WE) was performed for 35 minutes on the through holes provided in the A-2 step. As a result, the nozzle channels 111 were formed in which the ridgeline of each nozzle straight portion 1111 on the side facing the bonding surface Ba was substantially in contact with the end portions of the two tapered surfaces of each nozzle tapered portion 1112 on the side facing the ejection surface Bb and the two surfaces of each nozzle tapered portion 1112 perpendicular to the bonding surface Ba. Here, each nozzle tapered portion 1112 was formed on {111} planes.

### Example 5

SOI was used for the single-crystal silicon substrate B. After the single-crystal silicon substrate B was deep-etched in the step A-5, the SiO₂ layer (Box layer) was etched using an RIE apparatus to form through holes. The other conditions were the same as in Example 2.

### Example 6

The nozzle channels 111 were formed by the following steps A-1 to A-3. Step A-1: The front mask layer 112 and the back mask layer 113, each with the thickness of 1 μm, were formed by thermal oxidation on the single-crystal silicon substrate B with the thickness of 100 μm whose surfaces have the crystal orientations of the (110) plane and the (−1−10) plane. Step A-2: Using a positive photoresist, a substantially parallelogram pattern was formed on the front mask layer 112. The substantially parallelogram pattern has the base of 130 μm, the height of 50 μm, and the angles between the sides matching the angles between the (−111) plane, (1−1−1) plane, (1−11) plane, and (−11−1) plane. Next, dry etching (DE1) was performed using an RIE apparatus to form the opening pattern 114. After that, using a Si deep etching apparatus, the single-crystal silicon substrate B with the opening pattern 114 was dry etched (DE2) by the Bosch process to form holes each having the depth of 51 μm. Step a-3: After anisotropic wet etching (WE) was performed for 35 minutes on the holes provided after the step A-2, the mask layers were removed with hydrofluoric acid to form the nozzle channels 111 that include the straight communication paths 1113 and the nozzle tapered portions 1112.

### Example 7

The nozzle channels 111 were formed by the following steps B-1 to B-8. Step B-1: The front mask layer 112 and the back mask layer 113, each with the thickness of 3 μm, were formed by thermal oxidation on the single-crystal silicon substrate B with the thickness of 200 μm whose surfaces have the crystal orientations of {110} planes. Step B-2: Using the RIE apparatus, the pattern formed on the back mask layer 113 was dry etched (DE1) to form the nozzle pattern 115 having a perfectly circular shape with the diameter φ of 30 μm. For the etching gas, CHF₃ was used. Step B-3: Using a Si deep etching apparatus, the single-crystal silicon substrate B with the nozzle pattern 115 was dry etched (DE2) by the Bosch process. As a result, the nozzle straight portions 1111 each having the depth of 40.6 μm were formed. For the etching gas, SF₆ and C₄F₈ gases were used. Step B-4: The mask layers having the thickness of 1 μm were formed in the nozzle straight portions 1111 by thermal oxidation. Then, the mask layers only at the bottom were removed by an RIE apparatus to form the nozzle mask layers 116. Step B-5: Dry etching (DE2) by the Bosch process was performed using the Si deep etching apparatus to form the nozzle straight portions 1111 of deep holes each having the depth of 120 μm. Step B-6: Using a positive photoresist, a substantially parallelogram pattern was formed on the front mask layer 112. The substantially parallelogram pattern is set to 130 μm×50 μm and has the angles between the sides matching the angles between the (−111) plane, (1−1−1) plane, (1−11) plane, and (−11−1) plane. Then, dry etching (DE1) was performed using an RIE apparatus to form the opening pattern 114. After the dry etching (DE1), the photoresist was removed by immersion in acetone. Step B-7: Using the Si deep etching apparatus, the single-crystal silicon substrate B with the opening pattern 114 was dry etched (DE2). As a result, holes each having the depth of 100 μm were formed so as to communicate with the deep holes formed in the step B-5. In this case, the thickness (T) of the single-crystal silicon substrate B is 200 μm, the diameter (D) of each nozzle straight portion 1111 is 30 μm, the depth (h) of each nozzle straight portion 1111 is 40.6 μm, the width (L) of the opening pattern 114 in the {110} direction is 149.45 μm, and the depth (H) of each hole formed in the step B-7 is 100 μm. Therefore,

t−(H+(L/2)tan θ)≈47.17

From h−(D/2)tan θ≈29.99

t−(H+(L/2)tan θ)>h−(D/2)tan θ is satisfied. Step B-8: Anisotropic wet etching (WE) was performed by

immersion in a 40 wt KOH solution at 80° C. for 80 minutes to form the nozzle channels 111 that include the nozzle straight portions 1111, the nozzle tapered portions 1112, and the straight communication paths 1113. The mask layers were removed with hydrofluoric acid after the step B-8.

### Example 8

In the step B-1, a thick SiO₂ film with the thickness of 10 μm was formed by thermal oxidation as a non-wet etching layer on the ejection surface Bb. Then, the back mask layer 113 was formed. The other conditions were the same as in Example 7.

### Example 9

The nozzle pattern 115 provided in the step B-2 was formed in an elliptical shape having the major axis of 60.3 μm and the minor axis of 14.9 μm. The other conditions were the same as in Example 8.

### Example 10

For the single-crystal silicon substrate B, SOI was used. The other conditions were the same as in Example 7.

### Example 11

The nozzle pattern 115 provided in the step B-2 was formed in an elliptical shape having the major axis of 60.3 μm and the minor axis of 14.9 μm. Furthermore, the opening pattern 114 provided in the step B-6 was set to 130 μm×35 μm. The other conditions were the same as in Example 7. In this case, the thickness (T) of the single-crystal silicon substrate B is 200 μm, the width (D) of each nozzle straight portion 1111 is 14.9 μm, the depth (h) of each nozzle straight portion 1111 is 35.3 μm, the width (L) of the opening pattern 114 in the {110} direction is 149.45 μm, and the depth (H) of each hole formed in the step B-7 is 100 μm. Therefore,

t−(H+(L/2)tan θ)≈47.12

From h−(D/2)tan θ≈30.03

t−(H+(L/2)tan θ)≥h−(D/2)tan θ is satisfied.

### Comparative Example 1

Anisotropic wet etching (WE) was performed on the single-crystal silicon substrate B with the thickness of 200 μm whose surfaces have the crystal orientations of {100} planes. As a result, the nozzle channels 111 were formed such that the shape of each cross section in the left-right direction on the bonding surface Ba was a square shape of 130 μm×130 μm.

### Comparative Example 2

Anisotropic wet etching (WE) was performed on the single-crystal silicon substrate B with the thickness of 200 μm whose surfaces have the crystal orientations of {100} planes. As a result, the nozzle channels 111 were formed such that the shape of each cross section in the left-right direction on the bonding surface Ba was a square shape of 50 μm×50 μm.

The following Tests 1 and 2 were performed using the inkjet recording apparatus 1 on which the inkjet heads 10 that include the nozzle plates 110 of Examples 1 to 13 and Comparative Examples 1 and 2 described above were mounted.

### [Test 1. Injection Angle Test]

The UV ink heated to a viscosity of 8 cP was ejected at a drive voltage at which the average droplet speed was about 6 m/s. Then, it was evaluated to see within plus or minus how many degrees the injection angles of the 1280 nozzles lie.

### [Test 2. Maximum Speed Test]

At a drive frequency of 40 kHz, the ejection speed of the UV ink heated to a viscosity of 8 cP was increased from 5 m/s. Then, an injection speed at which the number of nozzles N in which ejection failure had occurred was 5 or more out of 100 nozzles was measured. In a case where the injection speed was 9 m/s or more, it was evaluated as “◯ (good)” because injection failure is less likely to occur even when the injection speed is high, that is, the meniscus stability is excellent. In a case where the injection speed was 11 m/s or more, it was evaluated as “⊚ (very good)” because the meniscus stability is particularly excellent.

The results of Tests 1 and 2 are shown in Table I.

TABLE 1

| | | EXAM- | EXAM- | EXAM- | EXAM- | EXAM- | EXAM- | EXAM- |
|---|---|---|---|---|---|---|---|---|
| | | PLE 1 | PLE 2 | PLE 3 | PLE 4 | PLE 5 | PLE 6 | PLE 7 |
| STRUCTURE | CRYSTAL ORIENTATION OF | 110 | 110 | 110 | 110 | 110 | 110 | 110 |
| | WAFER SURFACE | | | | | | | |
| | NOZZLE STRAIGHT | NO | YES | YES | YES | YES | NO | YES |
| | PORTION | | | | | | | |
| | NON-WET ETCHING LAYER | NO | NO | YES | YES | NO | NO | NO |
| | SOI WAFER | NO | NO | NO | NO | YES | NO | NO |
| | STRAIGHT | NO | NO | NO | NO | NO | YES | YES |
| | COMMUNICATION | | | | | | | |
| | PATH | | | | | | | |
| | TERRACE PLANE | NO | NO | YES | YES | YES | NO | NO |
| | | | | | (MINUSCULE) | | | |
| | TERRACE RIDGELINE | NO | YES | — | — | — | NO | YES |
| | NOZZLE PLATE | 50 × 130 | 50 × 130 | 50 × 130 | 50 × 130 | 50 × 130 | 50 × 130 | 50 × 130 |
| | HOLE SIZE | | | | | | | |
| | (μm) | | | | | | | |
| | PIEZOELECTRIC | 50 × 130 | 50 × 130 | 50 × 130 | 50 × 130 | 50 × 130 | 50 × 130 | 50 × 130 |
| | MATERIAL PLATE | | | | | | | |
| | HOLE SIZE | | | | | | | |
| | (μm) | | | | | | | |
| | NOZZLE DENSITY (dpi) | 360 | 360 | 360 | 360 | 360 | 360 | 360 |
| EVALUATION | EJECTION ANGLE | 1.0 | 0.2 | 0.2 | 0.2 | 0.2 | 1.0 | 0.2 |
| | (±°) | | | | | | | |
| | MENISCUS STABILITY | ⊚ | ◯ | ◯ | ⊚ | ◯ | ⊚ | ◯ |

| | | | | | | COMPAR- | COMPAR- |
|---|---|---|---|---|---|---|---|
| | | EXAM- | EXAM- | EXAM- | EXAM- | ATIVE | ATIVE |
| | | PLE 8 | PLE 9 | PLE 10 | PLE 11 | EXAMPLE 1 | EXAMPLE 2 |
| STRUCTURE | CRYSTAL ORIENTATION OF | 110 | 110 | 110 | 110 | 100 | 100 |
| | WAFER SURFACE | | | | | | |
| | NOZZLE STRAIGHT PORTION | YES | YES | YES | YES | YES | YES |
| | NON-WET ETCHING LAYER | YES | YES | NO | NO | NO | NO |
| | SOI WAFER | NO | NO | YES | NO | NO | NO |
| | STRAIGHT COMMUNICATION | YES | YES | YES | YES | NO | NO |
| | PATH | | | | | | |
| | TERRACE PLANE | YES | YES | YES | NO | NO | NO |
| | | | (MINUSCULE) | | | | |
| | TERRACE RIDGELINE | — | — | — | YES | YES | YES |
| | | | | | (MINUSCULE) | | |
| | NOZZLE PLATE | 50 × 130 | 50 × 130 | 50 × 130 | 50 × 130 | 130 × 130 | 50 × 50 |
| | HOLE SIZE | | | | | | |
| | (μm) | | | | | | |
| | PIEZOELECTRIC | 50 × 130 | 50 × 130 | 50 × 130 | 50 ×130 | 130 x 130 | 50 × 50 |
| | MATERIAL PLATE | | | | | | |
| | HOLE SIZE | | | | | | |
| | (μm) | | | | | | |
| | NOZZLE DENSITY (dpi) | 360 | 360 | 360 | 360 | 180 | 360 |
| EVALUATION | EJECTION ANGLE | 0.2 | 0.2 | 0.2 | 0.2 | 0.2 | — |
| | (±°) | | | | | | |
| | MENISCUS STABILITY | ◯ | ⊚ | ◯ | ⊚ | ◯ | — |

In Comparative Example 2, since the hole size was too small as 50 μm×50 μm, the ink could not be ejected even when the drive voltage was increased to 30 V.

### Evaluation

When Examples 1 to 11 are compared with Comparative Examples 1 and 2, in a case where the nozzle channels 111 are formed in the single-crystal silicon substrate B whose surfaces have the crystal orientations of {100} planes, the openings on the side of the bonding surface Ba can be formed only in a square shape. Therefore, it is only possible to manufacture either a nozzle plate with excellent injection characteristics but low nozzle density, or a nozzle plate with excellent nozzle density but low injection characteristics. On the other hand, in a case where the nozzle channels 111 are formed in the single-crystal silicon substrate B whose surfaces have the crystal orientations of {110} planes, the openings on the side of the bonding surface Ba can be formed in an elongated shape of 50 μm×130 μm. Therefore, it becomes possible to achieve both the high density of the nozzles N and the improvement of injection characteristics.

In particular, when Examples 1 and 6 are compared with other Examples, it is found that forming the nozzle straight portions 1111 in the nozzle channels 111 improves the injection angle and enhances the injection characteristics.

In addition, when Examples 1, 4, 6, 9, and 11 are compared with other Examples, it is found that not providing a terrace plane and a terrace ridgeline in each nozzle channel 111 or making the terrace plane and the terrace ridgeline minuscule enhances the meniscus stability, thereby providing the nozzle plate 110 in which ejection failure is less likely to occur.

### INDUSTRIAL APPLICABILITY

The present invention can be used for a nozzle plate, a droplet ejection head, a droplet ejecting apparatus, and a method for manufacturing a nozzle plate, which can achieve both high density of nozzles and preferable ejection characteristics.

### REFERENCE SIGNS LIST

B single-crystal silicon substrate
Ba bonding surface (first surface)
Bb ejection surface (second surface)
1 inkjet recording apparatus (droplet ejecting apparatus)
10 inkjet head (droplet ejection head)
110 nozzle plate
111 nozzle channel
1111 nozzle straight portion
1112 nozzle tapered portion
1113 straight communication path
112 front mask layer
113 back mask layer
114 opening pattern
115 nozzle pattern
116 nozzle mask layer
N nozzle

1. A nozzle plate made of a single-crystal silicon substrate, comprising
a plurality of nozzle channels that penetrates the nozzle plate, the plurality of nozzle channels each including a nozzle and each capable of ejecting droplets from the nozzle, wherein
the single-crystal silicon substrate includes a first surface and a second surface opposite the first surface,
the nozzle is formed on the second surface, and
the first surface and the second surface are {110} planes.

2. The nozzle plate according to claim 1, wherein each of the plurality of nozzle channels includes a surface on a {111} plane.

3. The nozzle plate according to claim 1, wherein
each of the plurality of nozzle channels includes a nozzle tapered portion having a channel area that gradually decreases from the first surface toward the second surface, the channel area being a cross-sectional area perpendicular to a droplet ejection direction, and
the nozzle tapered portion includes a {111} plane.

4. The nozzle plate according to claim 3, wherein the nozzle tapered portion is composed of {111} planes.

5. The nozzle plate according to claim 3, wherein
each of the plurality of nozzle channels includes a nozzle straight portion on a side of the nozzle tapered portion facing the second surface, and
a channel area of the nozzle straight portion is less than or equal to the channel area of the nozzle tapered portion.

6. The nozzle plate according to claim 5, further comprising
a non-wet etching layer formed by masking, thermal oxidation, or high-concentration doping, wherein
the nozzle straight portion has the non-wet etching layer for an end portion on a side facing the first surface.

7. The nozzle plate according to claim 5, wherein the nozzle straight portion is continuous with an end portion of the nozzle tapered portion on the side facing the second surface.

8. The nozzle plate according to claim 5, wherein in a view from the first surface, at least a portion of a ridgeline on a side facing the first surface among ridgelines constituting the nozzle straight portion is substantially in contact with a surface substantially perpendicular to the first surface among surfaces constituting the nozzle tapered portion.

9. The nozzle plate according to claim 1, wherein
each of the plurality of nozzle channels includes:
a nozzle tapered portion having a channel area that gradually decreases from the first surface toward the second surface, the channel area being a cross-sectional area perpendicular to a droplet ejection direction; and
a straight communication path that is continuous with a side facing the first surface of the nozzle tapered portion and includes a pair of facing surfaces substantially parallel to each other, wherein
the nozzle tapered portion and the straight communication path include a {111} plane.

10. The nozzle plate according to claim 9, wherein the nozzle tapered portion and the straight communication path are composed of {111} planes.

11. The nozzle plate according to claim 9, wherein
each of the plurality of nozzle channels includes a nozzle straight portion on a side of the nozzle tapered portion facing the second surface.

12. The nozzle plate according to claim 11, further comprising
a non-wet etching layer formed by masking, thermal oxidation, or high-concentration doping, wherein
the nozzle straight portion has the non-wet etching layer for an end portion on a side facing the first surface.

13. The nozzle plate according to claim 11, wherein the nozzle straight portion is continuous with an end portion of the nozzle tapered portion on the side facing the second surface.

14. The nozzle plate according to claim 11, wherein in a view from the first surface, at least a portion of a ridgeline on a side facing the first surface among ridgelines constituting the nozzle straight portion is substantially in contact with a surface substantially perpendicular to the first surface among surfaces constituting the nozzle straight communication path.

15. The nozzle plate according to claim 5, wherein
in a view from the first surface, an absolute value of a difference between a first distance and a second distance is within 0.5 μm, where the first distance is a distance from an intersection line to a farthest point or line on a ridgeline in a first direction parallel to the first surface or the second surface among <100> directions, the intersection line being where two tapered surfaces constituting the nozzle tapered portion intersect when virtually extended, the ridgeline being where a surface constituting the nozzle straight portion intersects with the two tapered surfaces constituting the nozzle tapered portion, and
the second distance is a distance from the intersection line to a farthest point or line on the ridgeline in a second direction parallel to the first surface or the second surface among <100> directions.

16. A droplet ejection head comprising the nozzle plate according to claim 1.

17. A droplet ejection apparatus comprising the droplet ejection head according to claim 16.

18. A method for manufacturing a nozzle plate of a droplet ejection head, comprising:
forming a front mask layer on a first surface of a single-crystal silicon substrate having a {110} surface crystal orientation;
forming an opening pattern that yields an opening of a nozzle channel in the front mask layer; and
performing anisotropic wet etching on the single-crystal silicon substrate from a surface through the opening pattern.

19. The method for manufacturing the nozzle plate according to claim 18, wherein in the performing, a nozzle tapered portion having a channel area that gradually decreases from the first surface toward a second surface of the single-crystal silicon substrate opposite the first surface is formed, the channel area being a cross-sectional area perpendicular to a droplet ejection direction.

20. The method for manufacturing the nozzle plate according to claim 19, wherein
the forming the front mask layer includes forming a back mask layer on the second surface of the single-crystal silicon substrate, and
the method further comprises:
forming a nozzle pattern that yields a nozzle in the back mask layer; and
forming a nozzle straight portion by performing penetration processing on the single-crystal silicon substrate from a surface through the nozzle pattern by dry etching, the forming the nozzle pattern and the forming the nozzle straight portion being performed after the performing.

21. A method for manufacturing a nozzle plate of a droplet ejection head, comprising:
forming a front mask layer on a first surface of a single-crystal silicon substrate having a {110} surface crystal orientation, and a back mask layer on a second surface of the single-crystal silicon substrate opposite the first surface;
of forming a nozzle pattern that yields a nozzle in the back mask layer;
of forming a hole that yields a nozzle straight portion by performing dry etching on the single-crystal silicon substrate from a back surface through the nozzle pattern to a middle;
forming a nozzle mask layer on a side wall of the hole;
performing dry etching on the single-crystal silicon substrate from the back surface through the hole;
forming an opening pattern that yields an opening in the front mask layer;
performing dry etching on the single-crystal silicon substrate from a front surface through the opening pattern; and
performing penetration processing on the single-crystal silicon substrate from the front surface and the back surface by anisotropic wet etching to form a nozzle channel that includes a nozzle straight portion, a nozzle tapered portion, and a straight communication path, wherein
a depth H of a hole formed in the performing dry etching on the single-crystal silicon substrate from the front surface satisfies the following (1):
(1) T−(H+(L/2) tan θ)≥h−(D/2) tan θ, where a thickness of the single-crystal silicon substrate is T, a diameter of the nozzle straight portion is D, a depth of the nozzle straight portion is h, a width of the opening in a <110> direction is L, and an angle formed by the first and second surfaces of the single-crystal silicon substrate and two tapered surfaces of {111} planes constituting the nozzle tapered portion is θ (θ=cos−1 (2/√6)≈35.26°.

22. The method for manufacturing the nozzle plate according to claim 21, wherein when the first surface is set to a (110) plane, a width of the nozzle pattern formed in the forming the nozzle pattern in a [−111] direction and a width of the nozzle pattern in a [1−1−1] direction are wider than a width of the opening pattern formed in the forming the opening pattern in a [−111] direction and a width of the opening pattern in a [1−1−1] direction.

23. The nozzle plate according to claim 11, wherein a maximum value of a channel area of the nozzle straight portion is less than or equal to the channel area of an end portion of the nozzle tapered portion on the side facing the first surface.
